(19) United States
(12) Patent Application Publication
(10) Pub. No.: US 2007/0018194 A1
(43) Pub. Date: Jan. 25, 2007

(54) Driving circuit

(75) Inventors: Takeshi Miki, Okazaki-city (JP); Mitsuhiro Kanayama, Takahama-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/451,371

(22) Filed: Jun. 13, 2006

(30) Foreign Application Priority Data
Jul. 19, 2005 (JP) 2005-208513

(51) Int. Cl. H01L 29/74

(52) U.S. Cl. 257/133

(57) ABSTRACT

When a PWM command signal reaches a low level, an input transistor turns on, an on-driving transistor turns off, Darlington-connected off-driving transistors connected in series with the on-driving transistor turn on, and an output MOSFET changes from an on-state to an off-state. At this time, a base current of the on-driving transistor is limited by its input resistor, and charge stored in a base region decreases. When the command signal reaches a high level again while the base current flows through the on-driving transistor, the charges stored in bases of the Darlington-connected transistors are quickly lost because of the existence of the resistor, a diode, and a second resistor, which reduces turn-off time.

### CROSS REFERENCE TO RELATED APPLICATION

This application relates to and incorporates herein by reference Japanese Patent Application No. 2005-208513 filed on Jul. 19, 2005.

### FIELD OF THE INVENTION

The present invention relates to a driving circuit that drives an output transistor according to a command signal.

Switching power supplies of step-down type that employ a switching device, a reactor, a capacitor, and a flywheel diode are disclosed in JP-A-8-19250, JP-A-2000-134916, and JP-A-2004-201466. These switching power supplies are driven by a pulse-width modulated (PWM) signal, and output a voltage corresponding to a duty ratio. A circuit for driving a MOSFET being a switching device is disclosed in JP-A-2000-134916.

As shown in FIG. 4, a conventional MOSFET driving circuit is used in a power supply IC or the like. A MOSFET (output transistor) Q1 functioning as a high side switch is connected between a power terminal 1 to which a voltage VB is applied and an output terminal 2, and an electric load 4 is connected between the output terminal 2 and the ground 3. When the MOSFET driving circuit is applied to the switching power supplies described in JP-A-8-19250, JP-A-2000-134916, and JP-A-2004-201466, the load 4 serves as a circuit that includes a reactor, a capacitor and a flywheel diode.

Between a power terminal 5 to which a step-up voltage VC boosted to be higher than the voltage VB is applied and the output terminal 2, transistors Q2 and Q3 are connected in a push-pull fashion with the gate of MOSFET Q1 therebetween. Between the power terminal 5 and the ground 3, a resistor R1 and a transistor Q4 are connected in series with the bases of the transistors Q2 and Q3 being connected therebetween.

In this construction, when a command signal Sc to be fed to the base of the transistor Q4 changes from a high level L to a low level L, the transistors Q4 and Q3 turn off, the transistor Q2 turns on, and the MOSFET Q1 turns on. Conversely, when the command signal Sc changes from the low level L to the high level H, the transistors Q4 and Q3 turn on, the transistor Q2 turns off, and the MOSFET Q1 turns off.

However, when a PWM frequency of the command signal Sc becomes high, the driving capability of the driving circuit including the transistors Q2 to Q4 becomes insufficient, so that the MOSFET Q1 cannot be instantaneously switched.

### SUMMARY OF THE INVENTION

The present invention has an object to provide a driving circuit that can drive an output transistor at higher switching frequencies.

According to a disclosed driving circuit, when a control voltage output circuit outputs a voltage necessary to turn on a transistor for off-driving according to an on-command signal, a base current flows into the transistor for off-driving, so that it turns on. As a result, charge stored in a gate capacitance of the output resistor is removed, a voltage between a gate and a source drops, and an output transistor turns off. In this case, since a resistor connected between the voltage output circuit and the base of the transistor for off-driving limits a base current of the transistor for off-driving, charge stored in the base of the transistor for off-driving can be decreased.

On the other hand, when, according to the on-command signal, the control voltage output circuit outputs a voltage of a power line, that is, a voltage sufficient to turn on the output transistor, a current for removing charge stored in the base of the transistor for off-driving flows into the base of the transistor for off-driving from the power line via a diode. Thereby, the charge stored in the base can be lost more quickly. The output transistor is turned on by a voltage afforded from an on-voltage supplying circuit. This circuit provides the resistor and the diode thereby to reduce a carrier storage effect of the transistor for off-driving, turn-off time of the transistor for off-driving can reduce turn-off time can be reduced, and thus the output transistor can be driven at higher switching frequencies.

### BRIEF DESCRIPTION OF THE DRAWINGS

The above and other objects, features and advantages of the present invention will become more apparent from the following detailed description made with reference to the accompanying drawings. In the drawings:

FIG. 1 is a circuit diagram showing a switching power supply of step-down type of one embodiment of the present invention;

FIGS. 2A to 2C signal diagrams showing simulation waveforms of a voltage VB, a voltage VS and an output voltage Vo, respectively, produced in the embodiment;

FIGS. 3A to 3C are signal diagrams showing simulation waveforms of a voltage VB, a voltage VS and an output voltage Vo, respectively, produced in an exemplary circuit; and

FIG. 4 is a circuit diagram showing a conventional MOSFET driving circuit.

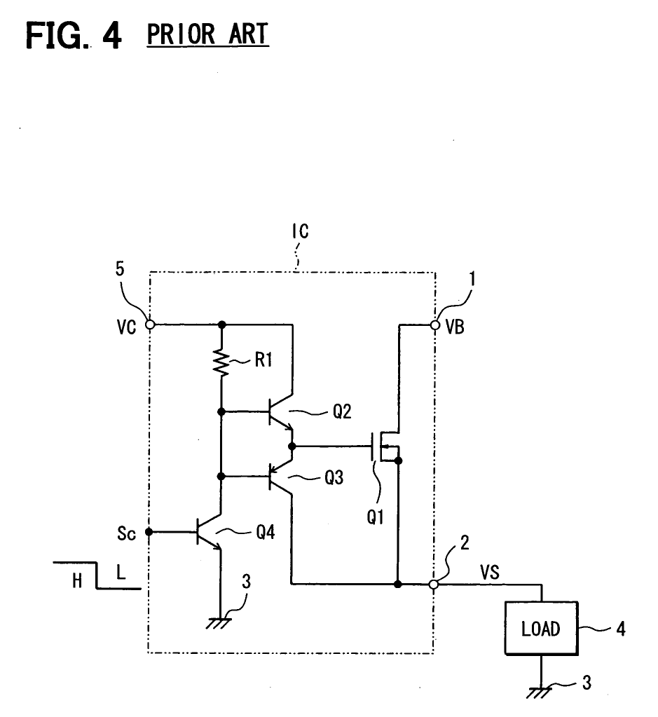

### DETAILED DESCRIPTION OF THE PREFERRED EMBODIMENTS

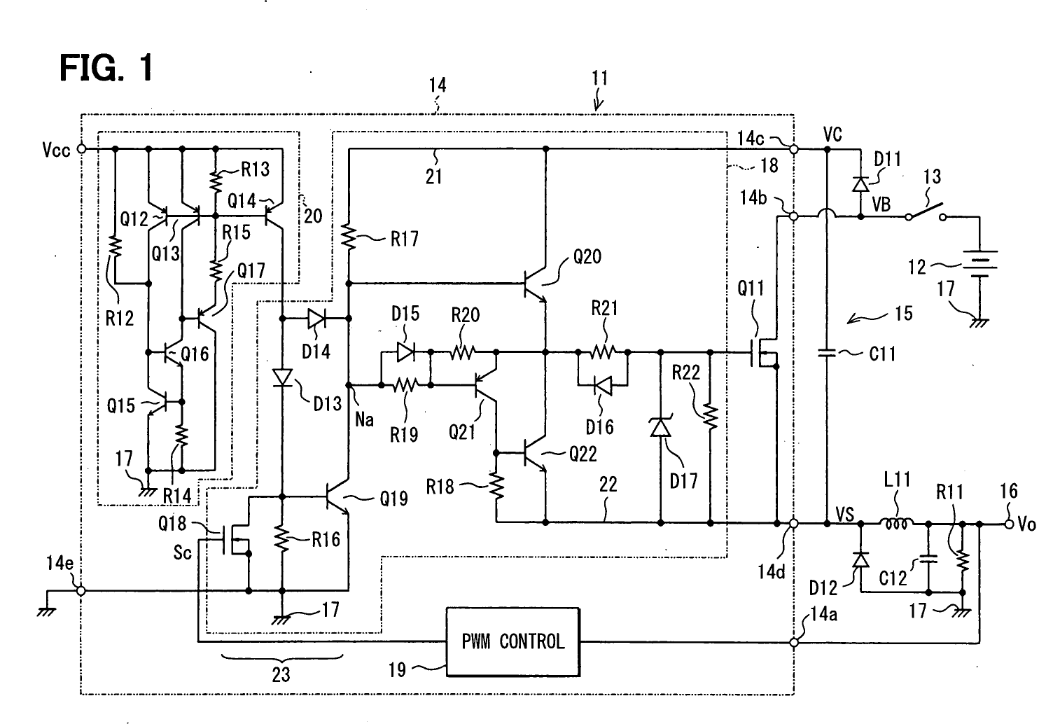

Referring to FIG. 1, a step-down type switching power supply is denoted with numeral 11.

The switching power supply 11 is operated with a voltage VB (e.g., 14V) from a battery 12 mounted in a vehicle via an ignition (IG) switch 13, and outputs a fixed voltage Vo (e.g., 6V). The switching power supply 11 is constructed by externally attaching some discrete parts to a power supply IC 14. A terminal 14a of the IC 14 is a feedback terminal of the output voltage Vo, and terminals 14b and 14c are power terminals to which the battery voltage VB and a step-up voltage VC boosted from the voltage VB are applied, respectively. A terminal 14d is an output terminal, and a terminal 14e is a ground terminal.

The power supply 11 is connected to an external circuit. In the external circuit, between the terminals 14b and 14c of the IC 14, a diode D11 is connected with the terminal 14b at the anode side, and a capacitor C11 is connected between the terminals 14c and 14d. A charge pump circuit 15 is constructed by the diode D11, the capacitor C11 and a MOSFET Q11.

A reactor L11 is connected between the terminal 14d of the IC 14 and the output terminal 16 of the switching power supply 11. A flywheel diode D12 having a polarity shown in the figure is connected between the terminal 14d and the ground 17, and a capacitor C12 and a resistor R11 are connected in parallel between the output terminal 16 and the ground 17. The output voltage Vo is fed back to the IC 14 via the terminal 14a.

The power supply IC 14 includes: LDMOS (Laterally Diffused MOS) FET Q11 of N channel type; a driving circuit 18 that drives the MOSFET Q11; a PWM control circuit 19 that controls the driving circuit 18; a constant current circuit 20 that supplies a constant current to the driving circuit 18; and a control power supply circuit (not shown). For convenience of the description of the circuit construction, internal wirings of the IC that are connected to the terminals 14c and 14d are called a power line 21 and an output line 22, respectively. The MOSFET Q11 is an output transistor that performs switching operations as a high side switch according to a command signal Sc; its drain and source are connected to the terminals 14b and 14d (output line 22).

The PWM control circuit 19 finds a voltage deviation of the output voltage Vo from a target output voltage (6V), and changes a duty ratio of the command signal Sc being a PWM signal, based on the voltage deviation, to perform constant voltage feedback control.

The constant current circuit 20 is composed of transistors Q12 to Q17 and resistors R12 to R15. The circuit construction is well-known as a constant current circuit of a self-biasing system. When a power supply voltage Vcc of e.g., 3.3V is fed from a control power circuit (not shown), the constant current circuit 20 outputs a constant current determined by VBE (Q15)/R14 from a collector of the transistor Q14.

The driving circuit 18 turns of/off the MOSFET Q11 according to the level (high/low) of the command signal Sc. A diode D13 and a resistor R16 are connected in series between the collector of the transistor Q14 and the ground 17. MOSFET Q18 is connected in parallel to a resistor R16. The above command signal Sc is fed to the gate of the MOSFET Q18.

A resistor R17 and a transistor Q19 are connected in series between the power line 21 and the ground 17. A base of the transistor Q19 is connected to a cathode of the diode D13. The diode D13, and a diode 14 between an anode of the diode D13 and a collector of the transistor Q19 are provided to restrict the transistor Q19 from saturating. A control voltage output circuit 23 is constructed by the MOSFET Q18, the transistor Q19, the resistors R16 and R17, and the diodes D13 and D14.

A transistor Q20 of NPN type (an on-voltage supplying circuit and a transistor for on-driving) and a transistor Q21 of PNP type (equivalent to a transistor for off-driving) constitute a push-pull circuit with their emitters connected with each other. A collector of the transistor Q20 is connected to the power line 21, and a collector of the transistor Q21 is connected to an output line 22 via a resistor R18. The transistors Q21 Q22 are Darlington-connected.

A first resistor R19 is connected between a base of the transistor Q21 and an output node Na of the control voltage output circuit 23. The resistor R19 is connected in parallel to a first diode D15 in a direction that blocks the passage of a base current while the transistor Q21 is ON. A second resistor R20 is connected between a base and an emitter of the transistors Q21.

Between emitters of the transistors Q20 and Q21 and a gate of the MOSFET Q11, a third resistor R21 is connected. The resistor R21 is connected in parallel to a second diode D16 so that charge stored in a gate capacitance of the MOSFET Q11 can pass while the transistor Q21 and Q22 are turned on. A resistor R22 and a Zener diode D17 for gate protection are connected between the gate and source of MOSFET Q11.

The embodiment performs a step-down operation by switching of the MOSFET Q11, when the IG switch 13 is turned on. When the command signal Sc is at a high level H, the MOSFET Q11 turns on, and a current flows from the battery 12 in the path of the IG switch 13, the terminal 14b, the MOSFET Q11, the terminal 14d, the reactor L11, the capacitor C12, and the ground 17. As a result, a current of the reactor L11 increases gradually, and the output voltage Vo rises.

A voltage VS of the terminal 14d (the output line 22 in the IC 14) at this time becomes substantially equal to the voltage VB of the battery 12. As described later, since the capacitor C11 is substantially charged to the voltage VB, the diode D11 turns off and prevents reverse flow, and the driving circuit 18 turns on the MOSFET Q11 using a step-up voltage, which is about 2·VB, with the charged voltage added.

When the command signal Sc is at a low level L, the MOSFET Q11 turns off, the diode D12 turns on, and a flywheel current flows through a closed loop of the reactor L11, the capacitor C12, and the diode D12. As a result, a current of the reactor L11 decreases gradually, and its energy is transferred to the capacitor C12. As a result of duty ratio control of the command signal Sc by the PWM control circuit 19, the output voltage Vo matches a target output voltage (6V).

A voltage VS of the terminal 14d while the MOSFET Q11 is OFF is −VF (about 0.7V) if a forward voltage of the diode D12 is VF. Accordingly, a current flows from the battery 12 in the path of the IG switch 13, the diode D11, and the capacitor C11, and the capacitor C11 is charged. When the switching operation of the MOSFET Q11 lasts, the capacitor C11 is charged to substantially the voltage VB because of a charging pump effect.

When the command signal Sc changes from the high level to the low level, the MOSFET Q18 turns off, the transistor Q19 turns on, and a voltage of the node Na drops to substantially the VF (forward voltage of p-n junction). As a result, the transistor Q20 turns off, the transistors Q21 and Q22 turn on, charge stored in a gate capacitance of the MOSFET Q11 is discharged via the diode D16 and the transistors Q21 and Q22, and the MOSFET Q11 turns from ON to OFF. As described above, the voltage VS of the output line 22 changes from VB to −VF.

In this transition, a base current of the transistor Q21 flows to the transistor Q19 via the resistor R19. Accordingly, unlike exemplary circuit in which the resistor R19 is not provided, the base current of the transistor Q21 is limited, and charge stored in a base region of the transistor Q21 decreases. When a PWM frequency of the command signal Sc is low, since the charge stored in a gate capacity of the MOSFET Q11 is almost all discharged within a period during which the Sc is at the low level, the base current of transistor Q21 becomes zero after the discharging.

When the command signal Sc changes from the low level to the high level, the MOSFET Q18 turns on, and the transistor Q19 turns off. When the PWM frequency of the command signal Sc is high, since the command signal Sc reaches the high level again when the base current is flowing to the transistor Q21, a carrier storage effect occurs in the transistor Q21. In this embodiment, however, since the diode D15 and the resistor R20 are provided in addition to the resistor R19, a delay of the turn-off of the transistors Q21 and Q22 by the carrier storage effect can be reduced.

Specifically, a current for removing charge stored in the base of the transistor Q21 flows from the power line 21 to the base of the transistor Q21 via the resistor R17 and the diode D15. The charge stored in the base are lost by a closed loop from the base of the transistor Q21 to the emitter via the resistor R20. As a result, the transistors Q21 and Q22 turn off quickly, with the result that a voltage of the node Na rises and the transistor Q20 turns on. Gate capacitance of the MOSFET Q11 is quickly charged by a current flowing through the transistor Q20 and the resistor R21, and the MOSFET Q11 turns on.

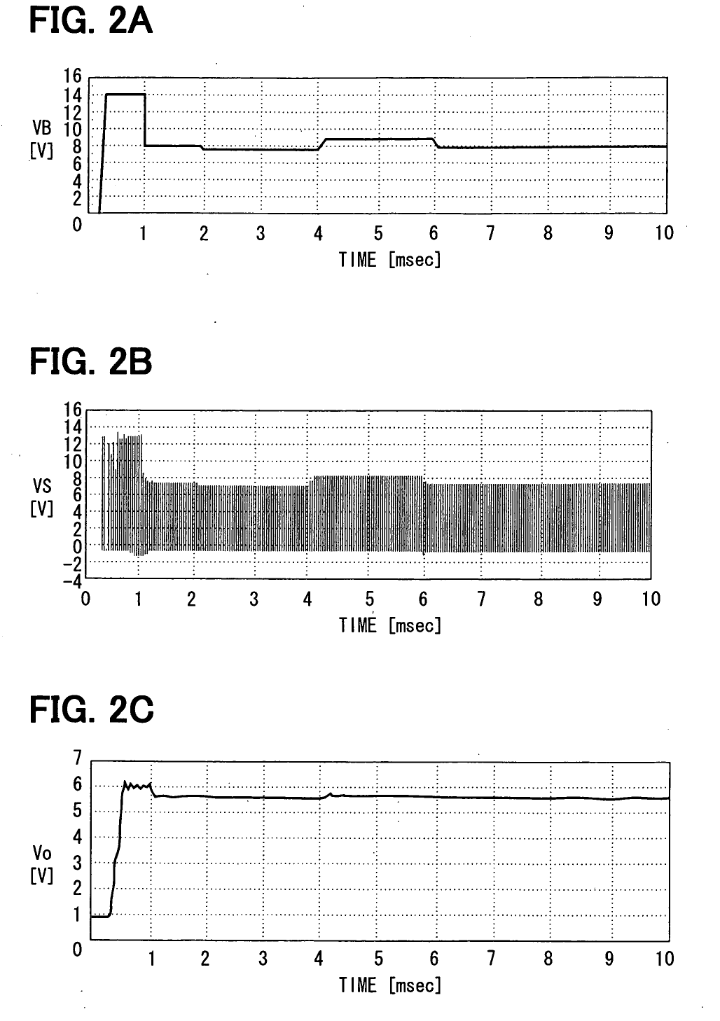

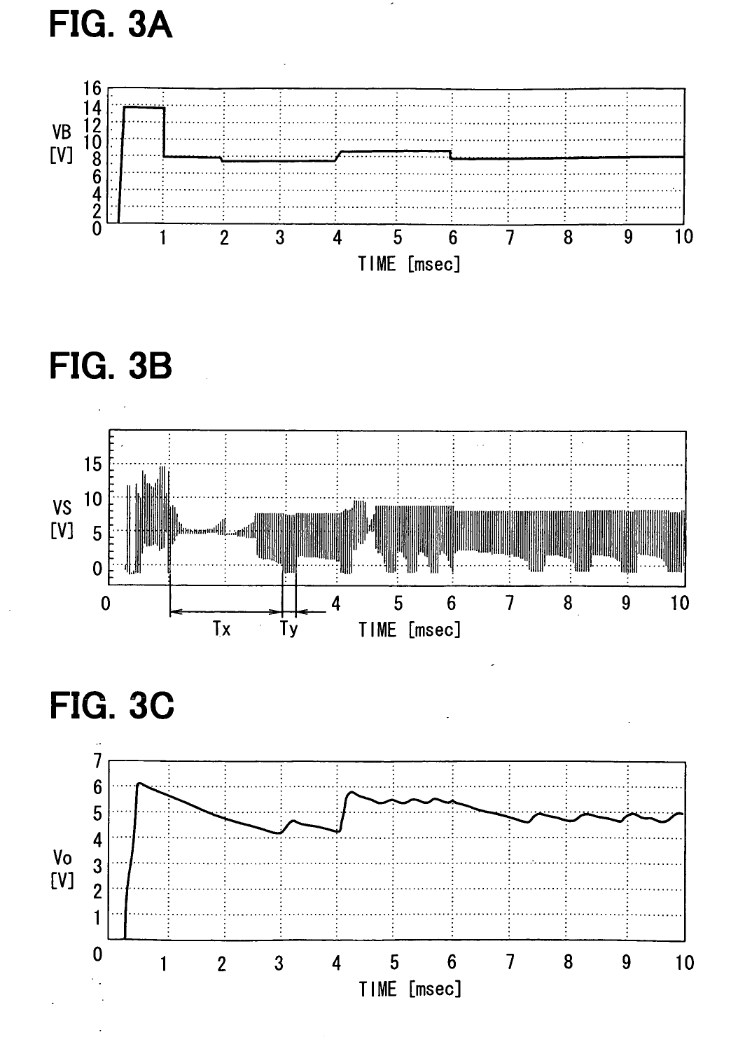

FIGS. 2A to 2C show a simulation result, that is, waveforms of voltage VB, voltage VS, and output voltage Vo in this embodiment. FIGS. 3A to 3C show a simulation result, that is, waveforms of voltage VB, voltage VS, and output voltage Vo in an exemplary circuit in which resistors R19 to R21, and diodes D15 and D16 are not provided. A PWM frequency of the command signal Sc is set to a frequency (e.g., 400 kHz) that would cause a problem in the exemplary circuit.

In this embodiment, as shown in FIGS. 2A to 2C, the amplitude of the voltage VS is always equal to VB. Specifically, the voltage VS while the MOSFET Q11 is ON is equal to VB, and the voltage VS while the MOSFET Q11 is OFF is equal to −VF (−0.7V). It will be understood that, in the simulation, the magnitude of the voltage VB is changed, while the voltage VS changes in amplitude like the voltage VB. This indicates that the MOSFET Q11 repeatedly turns on and off according to the command signal Sc, that is, the MOSFET Q11 performs switching operation normally. Since the voltage VB is dropped to about 8V, which is the most critical condition, the output voltage Vo is a little lower than the target output voltage 6V but is stabilized to an almost constant voltage.

On the other hand, in the case of the exemplary circuit, as shown in FIGS. 3A to 3C, an abnormality is found in the waveforms of the voltage VS and the output voltage Vo. In comparison between the waveforms of the voltage VS and the output voltage Vo, while the MOSFET Q11 is OFF, the output voltage V0 drops in a period (e.g., Tx) during which the voltage VS does not drop to −VF. When the MOSFET Q11 is OFF, the output voltage V0 rises in a period (e.g., Ty) during which the voltage VS drops to −VF. This indicates that the MOSFET Q11 does not sufficiently turn on or off in the period during which the voltage VS does not drop to −VF, and normal switching operation is not performed according to the command signal Sc.

Such an abnormality is considered to occur for the following reasons. Specifically, in the exemplary circuit in which no measures are taken for charge stored in the base of the transistor Q21, a period from when the command signal Sc changes to the high level until the transistor Q21 turns off is long. Therefore, the transistor Q20 turns on with delay, and consequently the MOSFET Q11 turns on with delay, so that a current flowing from the MOSFET Q11 to the reactor L11 decreases.

As a result, even if the command signal Sc changes from the high level to the low level, a flywheel current flowing via the reactor L11, the capacitor C12, and the diode D12 hardly flows, and a voltage of the voltage VS does not drop to −VF. At this time, a reverse current flows from the capacitor C12 through the reactor L11, the terminal 14d, the Zener diode D17 (or resistor R22), the diode D16 (or resistor R21), between emitter/base of the transistor Q21, the resistor R19, and the transistor Q19, and thereby the voltage VS of the output line 22 becomes almost equal to the output voltage Vo.

In this state, a sufficient amount of charge is not stored in the capacitor C11 of the charge pump circuit 15, and even when the command signal Sc changes to a high level, the step-up voltage VC becomes insufficient, so that the MOSFET Q11 cannot be sufficiently driven into an on-state. However, when the output voltage Vo becomes lower, since the voltage VS when the MOSFET Q11 is off also drops, a voltage between the terminals of the capacitor C11, that is, the step-up voltage VC rises, and the MOSFET Q11 starts a normal on-operation again. For this reason, the switching operation intermittently returns to a normal state as shown in FIGS. 3A to 3C.

As demonstrated by the simulation result, since the driving circuit 18 of this embodiment includes the resistors R19 and R20, and the diode D15 to reduce the carrier storage effect of the transistor Q21 for driving the MOSFET Q11 into an off-state, the transistors Q21 and Q22 can be quickly turned off and the transistor Q20 can be quickly turned on, and the MOSFET Q11 can be driven into an on- or off-state more quickly according to the command signal Sc than ever before. With this construction, a PWM frequency of the command signal Sc can be increased, the reactor L11 can be made compact, and the capacity of the MOSFET Q11 and the capacitor C11 can be reduced.

Since the resistor R21 is provided in a gate line of the MOSFET Q11, parasitic oscillation (overshoot and undershoot) caused by switching of the MOSFET Q11 can be reduced. Since the diode D16 is connected in parallel to the resistor R21, charge stored in the gate capacitance of the MOSFET Q11 can be quickly removed with the transistor Q21 turned on.

The embodiment may be modified in many ways. For instance, the resistor R20 may be omitted, although the resistor R20 enables the transistor Q21 to be turned off faster. The diode D16 may be omitted although the diode D16 enables the MOSFET Q11 to be turned off faster. When parasitic oscillation is small, the resistor R21 and the diode D16 may be omitted. A resistor may be used in place of the transistor Q20 although the transistor Q20 enables the MOSFET Q11 to be turned on faster.

In addition, an output transistor may be a bipolar transistor. When the transistor Q21 has a sufficient current driving capability, the transistor Q22 and the resistor R18 may be omitted. The driving circuit 18 may be applied to driving of MOSFETs and bipolar transistors in various devices, as well as a switching power supply.

What is claimed is:

1. A driving circuit that drives an output transistor according to an on/off command signal, comprising:
an off-driving transistor having an emitter and a collector connected between a gate and a source of the output transistor, the off-driving transistor supplying a voltage necessary to turn off the output transistor to a gate thereof by being turned on;
an on-voltage supplying circuit connected between a power line having a supply voltage sufficient to turn on the output transistor and the gate of the output transistor, the supplying circuit supplying the supply voltage to turn on the output transistor to the output transistor;
a resistor connected to a base of the off-driving transistor; and
a diode connected in parallel to the resistor in a direction that blocks a base current of the off-driving transistor when the off-driving transistor is turned on.

2. The driving circuit according to claim 1, further comprising:
an additional resistor connected between the base and emitter of the off-driving transistor.

3. The driving circuit according to claim 1, further comprising:
an additional resistor connected between the gate of the output transistor and a junction between the emitter of the off-driving transistor and the on-voltage supplying circuit.

4. The driving circuit according to claim 3, further comprising:
an additional diode connected in parallel to the additional resistor that allows charge stored in a gate capacitance of the output transistor to be passed when the off-driving transistor is turned on.

5. The driving circuit according to claim 1,
wherein the on-voltage supplying circuit includes an on-driving transistor controlled to an on-state or off-state in response to the on/off command signal.

6. The driving circuit according to claim 1,
wherein the off-driving transistor is Darlington-connected transistors.

7. The driving circuit according to claim 5, further comprising:
a control voltage output circuit connected to the base of the off-driving transistor through the resistor and the diode and to the base of the on-driving transistor, the control voltage output circuit outputting a voltage to control the off-driving transistor and the on-driving transistor according to the on/off command signal.
